(19) United States
(12) Patent Application Publication
(10) Pub. No.: US 2024/0405187 A1
(43) Pub. Date: Dec. 5, 2024

(54) OPTICAL MODULE AND DISPLAY DEVICE

(71) Applicant: HKC CORPORATION LIMITED, Shenzhen (CN)

(72) Inventors: Peng JIANG, Shenzhen (CN); Junfeng XIE, Shenzhen (CN)

(21) Appl. No.: 18/618,852

(22) Filed: Mar. 27, 2024

(30) Foreign Application Priority Data
May 30, 2023 (CN) 202310626917.1

(51) Int. Cl. H01L 33/64; H01L 25/075; H01L 25/16

(52) U.S. Cl. CPC H01L 33/648; H01L 25/0753; H01L 25/167

(57) ABSTRACT

An optical module includes a light plate and a heat dissipation structure. The heat dissipation structure includes a first substrate connected to the light plate, and a second substrate disposed under the first substrate. The first and second substrates are made of aluminum or an aluminum alloy material. A first anodized aluminum layer is disposed on a side of the first substrate adjacent to the second substrate. A second anodized aluminum layer is disposed on a side of the second substrate adjacent to the first substrate. A gap is defined between the first and second anodized aluminum layers, and there are disposed cooling droplets in the gap. When each light-emitting element is at a first heating value, the respective cooling droplet moves to a position under the light-emitting element. When each light-emitting element is at a second heating value, the respective coolant drop leaves from under the light-emitting element.

### CROSS-REFERENCE TO RELATED APPLICATIONS

This application claims the priority and benefit of Chinese patent application number 202310626917.1, titled “Optical Module and Display Device” and filed May 30, 2023 with China National Intellectual Property Administration, the entire contents of which are incorporated herein by reference.

### TECHNICAL FIELD

This application relates to the field of display, and more particularly relates to an optical module and a display device.

### BACKGROUND

The description provided in this section is intended for the mere purpose of providing background information related to this application but doesn't necessarily constitute prior art.

As the lamp beads of a mini LED display are designed with more and more partitions, the numbers of LED lamp beads and chips are also increasing. The mini LED lamp beads in high-brightness partitions have high power, high brightness, and significant heat generation, which will cause local heating of the display panel and cause color shift of the display panel.

A cooling fan or heat dissipation hole may be added at the position of the lamp bead, or to design a heat dissipation structure on the surface of the lamp bead to dissipate heat from the lamp bead. However, these heat dissipation methods are all passive heat dissipation and cannot dissipate the high-density heat generated by a local position of the LED chip or by a single mini LED light-emitting element in a short period of time. Furthermore, the heat dissipation methods by means of the fixed structure cannot quickly and locally cool down the mini LEDs having an uneven heat generation structure.

Therefore, how to quickly cool down the local heat generated by a mini LED in a relatively short period of time has become an urgent problem that needs to be solved in this field.

### SUMMARY

In view of the above, it is a purpose of this application to provide an optical module and display device that may quickly cool down the local heat generated by mini LEDs in a relatively short period of time.

This application discloses an optical module. The optical module includes a light plate. A plurality of light-emitting elements are arranged in an array on the light plate. The optical module further includes a heat dissipation structure, which is disposed on a side of the light plate facing away from the light-emitting element. The heat dissipation structure includes a first substrate and a second substrate. The first substrate is disposed above the second substrate and is connected to the light plate. Both the first substrate and the second substrate are made of aluminum or an aluminum alloy material. A first anodized aluminum layer is disposed on the side of the first substrate adjacent to the second substrate. A second anodized aluminum layer is disposed on a side of the second substrate adjacent to the first substrate. There is defined a gap between the first anodized aluminum layer and the second anodized aluminum layer, and there is disposed a cooling droplet in the gap. When the light-emitting element is at a first heating value, the cooling droplet moves to the position under the light-emitting element. When the light-emitting element is at a second heating value, the cooling droplet leaves from under the light-emitting element.

In some embodiments, a third substrate is disposed between the first substrate and the second substrate. A third anodized aluminum layer is disposed on a side of the third substrate adjacent to the first substrate. A fourth anodized aluminum layer is disposed on a side of the third substrate adjacent to the second substrate. The third substrate divides the gap between the first substrate and the second substrate to form a first heat dissipation layer and a second heat dissipation layer, where the first heat dissipation layer is located above the second heat dissipation layer. The cooling droplets are disposed in the first heat dissipation layer, or alternatively the cooling droplets are disposed in both the first heat dissipation layer and the second heat dissipation layer.

In some embodiments, the third substrate includes a valve. The heat dissipation structure further includes a driver chip, which is disposed outside the third substrate and electrically connected to the valve. The driver chip controls the opening or closing of the valve to connect or disconnect the first heat dissipation layer and the second heat dissipation layer.

In some embodiments, there are cooling droplets only in the first heat dissipation layer. Each of the cooling droplets is arranged under the respective light-emitting element. The third substrate includes one valve at a position corresponding to each cooling droplet.

In some embodiments, multiple adjacent light-emitting elements form a light-emitting section. A cooling droplet is disposed in the first heat dissipation layer at a position corresponding to each of the light-emitting sections, or alternatively a cooling droplet is disposed on each of the first heat dissipation layer and the second heat dissipation layer at a position corresponding to each of the light-emitting sections. The cooling droplet has an equal area to that of the light-emitting section. The third substrate defines a connection channel arranged corresponding to the position between two adjacent light-emitting sections, and a control electrode is disposed on each of the connection channels and is electrically connected to the driver chip. The driver chip controls a polarity of the control electrode to control the opening or closing of the connection channel.

In some embodiments, the light-emitting section includes a first light-emitting section, a second light-emitting section, a third light-emitting section, and a fourth light-emitting section adjacently arranged. The first light-emitting section, the second light-emitting section, the third light-emitting section, and the fourth light-emitting section are arranged in a square shape. The connection channel includes a first connection channel and a second connection channel. The first connection channel is sequentially arranged between the first light-emitting section and the second light-emitting section, between the second light-emitting section and the third light-emitting section, between the third light-emitting section and the fourth light-emitting section, and between the fourth light-emitting section and the first light-emitting section. The second connection channel is diagonally arranged between the first light-emitting section and the third light-emitting section, and between the second light-emitting section and the fourth light-emitting section.

In some embodiments, a first electrode is disposed on a side of the first substrate adjacent to the third substrate and at a position corresponding to the control electrode, and a second electrode is disposed on a side of the second substrate adjacent to the third substrate and at a position corresponding to the control electrode. The first electrode and the second electrode are each electrically connected to the driver chip. The driver chip controls each of the first electrodes and the control electrode to form a voltage difference or a zero voltage difference therebetween, and each of the second electrodes and the control electrode to form a voltage difference or a zero voltage difference therebetween. When a voltage difference is formed between each control electrode and the respective first electrode or the respective second electrode, the cooling droplet flows through the connection channel. When a zero voltage difference is formed between each control electrode and the respective first electrode or the respective second electrode, the cooling droplet does not flow through the connection channel.

In some embodiments, the first electrode, the second electrode, and the control electrode are all made of thermally conductive metal materials.

In some embodiments, the heat dissipation structure further includes a low-temperature coolant storage area, a high-temperature coolant storage area, and a cooling device. The low-temperature coolant storage area and the high-temperature coolant storage area are respectively connected to edges of the first substrate and the second substrate in different directions. The low-temperature coolant storage area, the high-temperature coolant storage area, and the cooling device are connected through cooling pipes. A one-way valve is disposed in each of the cooling pipes to control the flow of coolant in the high-temperature coolant storage area to the low-temperature coolant storage area. The low-temperature coolant storage area and the high-temperature coolant storage area may each include a plurality of control valves between the first heat dissipation layer and the second heat dissipation layer. The plurality of control valves are electrically connected to the driver chip. The driver chip controls the opening or closing of each of the control valves.

This application further discloses a display device, which includes a display panel. The display device further includes the above-mentioned optical module, where the display panel is arranged on a side of a light-emitting surface of the optical module.

In this application, a heat dissipation structure is disposed under the light plate. The first substrate and the second substrate of the heat dissipation structure are both made of aluminum or an aluminum alloy material, making it easier to form the first anodized aluminum layer and the second anodized aluminum layer on the first substrate and the second substrate. The surface properties of the first anodized aluminum layer and the second anodized aluminum layer form super-amphiphilic micro-nano channels used for the movement of the cooling droplets. By means of the three-phase contact line state of the aluminum plate, the anodized aluminum, and the cooling droplet, the cooling droplet may quickly diffuse and move on the porous and orderly anodized aluminum surface, and the cooling droplet may be prevented from splitting while it is moving efficiently, ensuring that the cooling droplet may maintain an effective cooling range and move as a whole. The cooling droplet between the first anodized aluminum layer and the second anodized aluminum layer may quickly wet, cover and absorb the heat of the light-emitting element, continuously reducing the temperature of the light-emitting element in the high-temperature display area in a shorter time, and ensuring that the temperature difference between adjacent light-emitting elements is relatively small to avoid affecting the display effect.

### BRIEF DESCRIPTION OF DRAWINGS

The accompanying drawings are used to provide a further understanding of the embodiments according to this application, and they constitute a part of the specification. They are used to illustrate the embodiments according to this application, and explain the principle of this application in conjunction with the text description. Apparently, the drawings set forth in the following description merely represent some embodiments of the present application, and for those having ordinary skill in the art, other drawings may also be obtained based on these drawings without investing creative efforts. A brief description of the accompanying drawings is provided as follows.

FIG. 1 is a schematic diagram of a first embodiment of an optical module according to the present application.

FIG. 2 is a schematic diagram of a second embodiment of the optical module according to the present application.

FIG. 3 is a top view of the second embodiment of the optical module according to the present application.

FIG. 4 is a schematic diagram of a third embodiment of the optical module according to the present application.

FIG. 5 is a schematic diagram of a fourth embodiment of the optical module according to the present application.

FIG. 6 is a top view of a fifth embodiment of the optical module according to the present application.

FIG. 7 is a partial top view of the fifth embodiment of the optical module according to the present application.

FIG. 8 is a top view of a sixth embodiment of the optical module according to the present application.

FIG. 9 is a schematic diagram of a seventh embodiment of the optical module according to the present application.

FIG. 10 is a schematic diagram of an embodiment of a display device according to the present application.

In the drawings: 10, display device; 100, optical module; 200, display panel; 110, light plate; 111, light-emitting element; 120, heat dissipation structure; 121, first substrate; 122, first anodized aluminum layer; 123, second substrate; 124, second anodized aluminum layer; 125, third substrate; 126, third anodized aluminum layer; 127, fourth anodized aluminum layer; 128, valve; 130, driver chip; 131, first heat dissipation layer; 132, second heat dissipation layer; 140, cooling droplet; 150, light-emitting section; 151, first light-emitting section; 152, second light-emitting section; 153, third light-emitting section; 154, fourth light-emitting section; 160, connection channel; 161, control electrode; 162, first connection channel; 163, second connection channel; 164, first electrode; 165, second electrode; 170, low-temperature coolant storage area; 180, high-temperature coolant storage area; 190, cooling device; 191, cooling pipe; 192, one-way valve; 193, control valve.

### DETAILED DESCRIPTION OF EMBODIMENTS

It should be understood that the terms used herein, the specific structures and function details disclosed herein are intended for the mere purposes of describing specific embodiments and are representative. However, this application may be implemented in many alternative forms and should not be construed as being limited to the embodiments set forth herein.

Hereinafter this application will be described in further detail with reference to the accompanying drawings and some optional embodiments.

FIG. 1 is a schematic diagram of a first embodiment of an optical module according to this application. As shown in FIG. 1, this application discloses an optical module 100. The optical module 100 includes a light plate 110, on which a plurality of light-emitting elements 111 are arranged in an array. The optical module 100 further includes a heat dissipation structure 120. The heat dissipation structure 120 is disposed on the side of the light plate 110 facing away from the light-emitting elements 111. The heat dissipation structure 120 includes a first substrate 121 and a second substrate 123. The first substrate 121 is disposed above the second substrate 123 and is connected to the light plate 110. The first substrate 121 and the second substrate 123 are both made of aluminum or an aluminum alloy material. A first anodized aluminum layer 122 is disposed on the side of the first substrate 121 adjacent to the second substrate 123. A second anodized aluminum layer 124 is disposed on the side of the second substrate 123 adjacent to the first substrate 121. There is a gap between the first anodized aluminum layer 122 and the second anodized aluminum layer 124, and there is disposed a cooling droplet 140 in the gap. When the light-emitting element 111 is at a first heating value, the cooling droplet 140 moves under the light-emitting element 111. When the light-emitting element 111 is at a second heating value, the cooling droplet 140 leaves from under the light-emitting element 111.

In this application, a heat dissipation structure 120 is disposed under the light plate 110. The first substrate 121 and the second substrate 123 of the heat dissipation structure 120 are both made of aluminum or an aluminum alloy material, making it easier to form the first anodized aluminum layer 122 and the second anodized aluminum layer 124 on the first substrate 121 and the second substrate 123. The surface properties of the first anodized aluminum layer 122 and the second anodized aluminum layer 124 form super-amphiphilic micro-nano channels used for the movement of the cooling droplets 140. By means of the three-phase contact line state of the aluminum plate, the anodized aluminum, and the cooling droplet 140, the cooling droplet 140 may quickly diffuse and move on the porous and orderly anodized aluminum surface, and the cooling droplet 140 may be prevented from splitting while it is moving efficiently, ensuring that the cooling droplet 140 may maintain an effective cooling range and move as a whole. The cooling droplet 140 between the first anodized aluminum layer 122 and the second anodized aluminum layer 124 may quickly wet, cover and absorb the heat of the light-emitting element 111, continuously reducing the temperature of the light-emitting element 111 in the high-temperature display area in a shorter time, and ensuring that the temperature difference between adjacent light-emitting elements 111 is relatively small to avoid affecting the display effect.

In addition, the anodized aluminum oxide layer in this application may be micro-nano anodized aluminum oxide. The heat dissipation performance of micro-nano anodized aluminum is very excellent. It may quickly reduce the surface temperature in the initial stage, and may continue to reduce the surface temperature in a rapid manner. It is calculated that the heat dissipation rate of the micro-nano anodized aluminum surface in the initial stage within 1s is 29.35° C./s, while the heat dissipation rates of the aluminum plate and anodized aluminum are 13.34° C./s and 19.69° C./s, respectively. Therefore, the heat dissipation rate may also be improved through the first anodized aluminum layer 122 and the second anodized aluminum layer 124 made of micro-nano anodized aluminum material.

It should be noted that the first heating value mentioned in this application is the high temperature value reached by the light-emitting element 111 in a relatively short time, and the second heating value is the temperature value of the light-emitting element 111 in a normal state. Research shows that when the temperature of the operating environment of mini LED is 30° C., the service of the mini LED is 20 times longer than that at 70° C. Therefore, the first heating value may be set, but not limited to, range from 60° C. to 80° C., which belongs to the high temperature value range reached by the light-emitting element 111 in a short time, and the second heating value may be set, but not limited to, range from 20° C. to 40° C., which belongs to the temperature value range of the light-emitting element 111 in the normal state. Of course, this application merely uses exemplary data to explain the relationship between the first heating value and the second heating value for easy understanding. The actual temperature value ranges of the first heating value and the second heating value may be set depending on actual conditions during the actual use of the optical module 100, and are not specifically limited in this application.

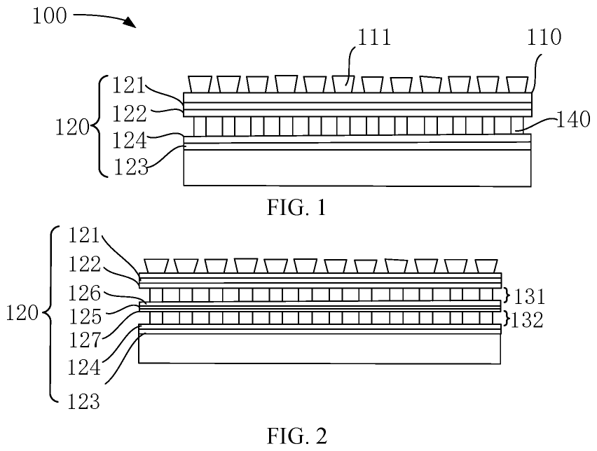

FIG. 2 is a schematic diagram of a second embodiment of the optical module according to this application. As shown in FIG. 2, the embodiment shown in FIG. 2 is an improvement based on FIG. 1. A third substrate 125 is further arranged between the first substrate 121 and the second substrate 123. A third anodized aluminum layer 126 is disposed on the side of the third substrate 125 adjacent to the first substrate 121. A fourth anodized aluminum layer 127 is disposed on the side of the third substrate 125 adjacent to the second substrate 123. The third substrate 125 divides the gap between the first substrate 121 and the second substrate 123 to form a first heat dissipation layer 131 and a second heat dissipation layer 132. The first heat dissipation layer 131 is located above the second heat dissipation layer 132. A cooling droplet 140 is disposed in the first heat dissipation layer 131. Alternatively, cooling droplets 140 are disposed in the first heat dissipation layer 131 and the second heat dissipation layer 132.

In this embodiment, the third substrate 125 is used to divide the entire heat dissipation structure 120 into a first heat dissipation layer 131 and a second heat dissipation layer 132, and cooling droplets 140 may be disposed in both the first heat dissipation layer 131 and the second heat dissipation layer 132. The cooling droplets 140 may move quickly within the first heat dissipation layer 131 and the second heat dissipation layer 132, so that the first heat dissipation layer 131 and the second heat dissipation layer 132 realize double-layer heat dissipation for the light plate 110. Furthermore, the dual heat dissipation layer design allows the cooling droplets 140 that are needed to perform cooling to quickly reach the high-temperature coolant storage area 180 through the two heat dissipation layers simultaneously. In addition, the load of the cooling device 190 is reduced, further improving the cooling efficiency.

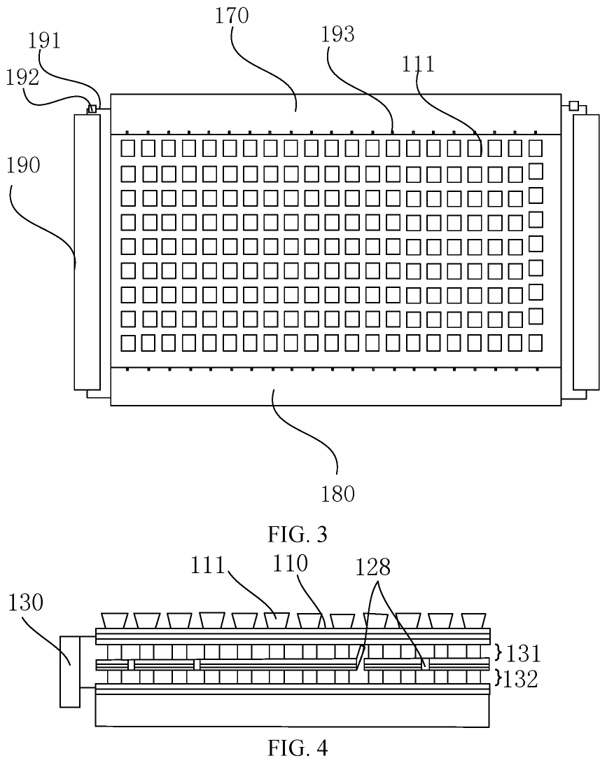

FIG. 3 is a top view of the second embodiment of the optical module according to this application. As shown in FIG. 3, the heat dissipation structure 120 further includes a low-temperature coolant storage area 170, a high-temperature coolant storage area 180, and a cooling device 190. The low-temperature coolant storage area 170 and the high-temperature coolant storage area 180 are respectively connected to edges of the first substrate 121 and the second substrate 123 in different directions. The low-temperature coolant storage area 170, the high-temperature coolant storage area 180, and the cooling device 190 are connected with each other through cooling pipes 191. The cooling pipe 191 includes a one-way valve 192 to control the flow of coolant from the high-temperature coolant storage area 180 to the low-temperature coolant storage area 170. A plurality of control valves 193 are disposed between the low-temperature coolant storage area 170 and the high-temperature coolant storage area 180 corresponding to the first heat dissipation layer 131 and the second heat dissipation layer 132. The plurality of control valves 193 are electrically connected to the driver chip 130. The driver chip 130 controls the opening or closing of each control valve 193.

The low-temperature coolant storage area 170 in this application is used to store coolant at a normal temperature. The high-temperature coolant storage area 180 is used to store coolant that has absorbed the heat of the light-emitting element 111. The cooling device 190 is connected to the coolant storage areas of different temperatures through the cooling pipes 191, and is used to cool the coolant in the high temperature coolant storage area 180 and transfer it to the low temperature coolant storage area 170. The one-way valve 192 of the cooling pipe 191 may be a Tesla one-way valve 192 or other one-way valve 192 structures.

The coolant mainly used for heat dissipation may be conventional coolants, or liquid metals or liquid alloys. When the cooling droplets 140 need to flow out from the low-temperature coolant storage area 170, it is only required to open the control valves 193 of the low-temperature coolant storage area 170, so that the cooling droplets 140 will flow out from the coolant storage area. When the cooling droplets 140 finish absorbing the heat and enter the high-temperature coolant storage area 180, closing the control valves 193 of the high-temperature coolant storage area 180 may effectively prevent the cooling droplets 140 from flowing back to the first heat dissipation layer 131 and the second heat dissipation layer 132.

FIG. 4 is a schematic diagram of a third embodiment of the optical module according to this application. As shown in FIG. 4, the embodiment shown in FIG. 4 is an improvement based on FIG. 3. A valve 128 is disposed in the third substrate 125. The heat dissipation structure 120 further includes a driver chip 130. The driver chip 130 is disposed outside the third substrate 125 and is electrically connected to the valve 128. The driver chip 130 controls the opening or closing of the valve 128 to connect or seal the first heat dissipation layer 131 and the second heat dissipation layer 132 from each other.

Since the first heat dissipation layer 131 is closer to the light plate 110, and the second heat dissipation layer 132 is farther away from the light plate 110, the actual temperature of the cooling droplet 140 in the first heat dissipation layer 131 after absorbing the heat of the light-emitting element 111 will be higher than the actual temperature of the cooling droplet 140 in the second heat dissipation layer 132. As such, the valve 128 is set in the third substrate 125, namely the valve 128 is set between the first heat dissipation layer 131 and the second heat dissipation layer 132, and the opening or closing of the valve 128 is controlled by the driver chip 130. When the cooling droplet 140 in the first heat dissipation layer 131 has a relatively high temperature after the heat absorption is completed, the valve 128 may be opened so that the high temperature cooling droplet 140 in the first heat dissipation layer 131 flows into the second heat dissipation layer 132. Since there is a temperature difference between the lower temperature cooling droplet 140 in the second heat dissipation layer 132 and the high temperature cooling droplet 140 flowing into the second heat dissipation layer 132 from the first heat dissipation layer 131, the high-temperature cooling droplet 140 in the first heat dissipation layer 131 may undergo a preliminary cooling, so that all the cooling droplets 140 in the second heat dissipation layer 132 may tend to have a consistent temperature, and then are recycled into the high temperature coolant storage area 180 through the second heat dissipation layer 132. This further accelerates the cooling rate of the high-temperature cooling droplets 140 and improves the recycling efficiency of the cooling droplets 140.

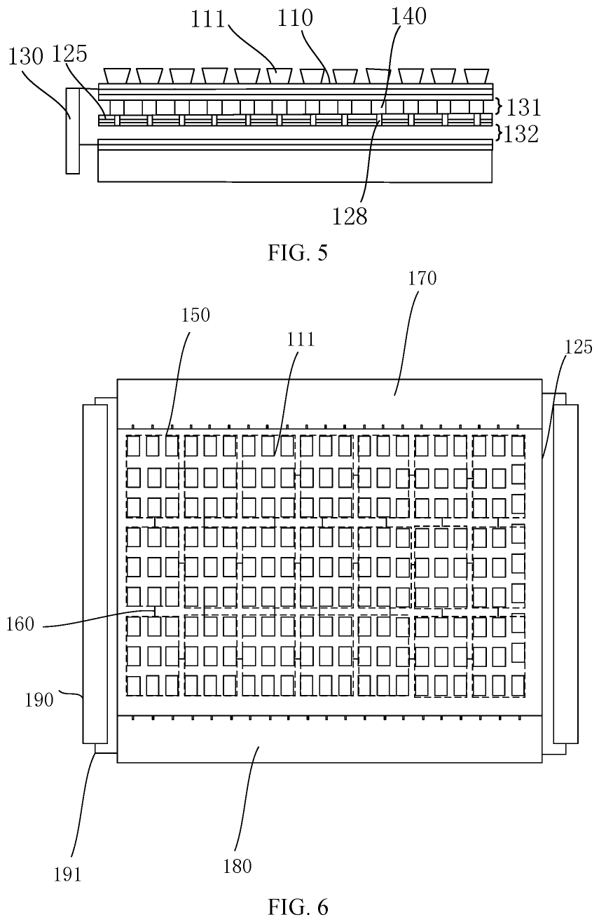

FIG. 5 is a schematic diagram of a fourth embodiment of the optical module according to this application. As shown in FIG. 5, the embodiment shown in FIG. 5 is an improvement based on FIG. 4. There are cooling droplets 140 only in the first heat dissipation layer 131. One cooling droplet 140 is disposed correspondingly under each light-emitting element 111. The third substrate 125 includes a valve 128 corresponding to the position of each cooling droplet 140.

Different from the previous embodiment, in this embodiment, the cooling droplet 140 are disposed only in the first heat dissipation layer 131 adjacent to the light plate 110 at a position corresponding to the position under each light-emitting element 111, while no cooling droplets 140 are arranged in the second heat dissipation layer 132. After each cooling droplet 140 absorbs heat from the respective light-emitting element 111, the corresponding valve 128 is opened, and the cooling droplet 140 that has completed the heat absorption will fall to the second heat dissipation layer 132, and return to the high temperature coolant storage area 180 through the second heat dissipation layer 132. This may effectively prevent the cooling droplet 140 that has absorbed heat from causing heat interference to the light-emitting elements 111 at other positions when moving in the first heat dissipation layer 131, and it is conducive to recycling the cooling droplets 140 that have completely absorbed heat, which is beneficial to reducing the overall power consumption of the optical module 100.

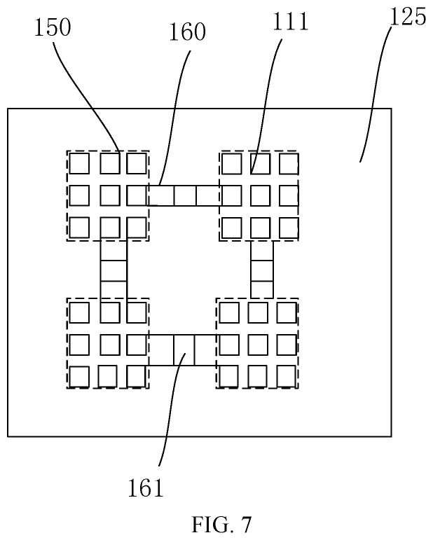

FIG. 6 is a top view of a fifth embodiment of the optical module according to this application. FIG. 7 is a partial top view of the fifth embodiment of the optical module according to this application. As shown in FIGS. 6 and 7, the embodiment shown in FIG. 6 is an improvement based on FIG. 1. Multiple adjacent light-emitting elements 111 form a light-emitting section 150. A cooling droplet 140 may be disposed in the first heat dissipation layer 131 at a position corresponding to each light-emitting section 150, and the area of the cooling droplet 140 may be equal to the area of the light-emitting section 150. Alternatively, a cooling droplet 140 may be disposed on each of the first heat dissipation layer 131 and the second heat dissipation layer 132 at a position corresponding to the position of each light-emitting section 150, and the area of each cooling droplet 140 may be equal to the area of the light-emitting section 150. The third substrate 125 may include a connection channel 160 corresponding to the position between two adjacent light-emitting sections 150. Each connection channel 160 may include a control electrode 161. The control electrode 161 may be electrically connected to the driver chip 130. The driver chip 130 controls the polarity of the control electrode 161 to control the opening or closing of the connection channel 160.

In this embodiment, a connection channel 160 is disposed between two adjacent light-emitting sections 150. The connection channel 160 may be made of the same material as the first anodized aluminum layer 122 and the second anodized aluminum layer 124, or it may be made of different materials. This application does not make specific limitations, and merely takes the connection channel 160 as an anodized aluminum material for illustration purposes.

Since the droplet has a certain shape when placed on the aluminum plate, the three-phase contact line of the droplet is fixed in the air and does not involve capillary effects. However, when surface structures are introduced, the forces acting on the three-phase contact line would change due to additional capillary effects. The surface of the anodized aluminum layer has tubular structures, which add a capillary effect to the three-phase contact line, but its vertical capillary force is greater than 0, while the horizontal capillary force is equal to 0. In this case, the additional capillary effect has little effect on the spread of droplets. In this application, the surface-interconnected connection channels 160 of anodized aluminum material may be made by anodizing method to be not perpendicular to the aluminum plate, so that the capillary effect is greater than 0 and both the vertical capillary force and the horizontal capillary force are greater than 0, so that the droplets may spread quickly on the surface of the connection channels 160.

Since the first heat dissipation layer 131 is closest to the light plate 110, it will directly affect the heat dissipation of the light plate 110. Therefore, in this embodiment, the cooling droplets 140 may be disposed in the first heat dissipation layer 131 only at the position corresponding to each light-emitting section 150, so that the first heat dissipation layer 131 may dissipate heat for each light-emitting section 150 through the cooling droplets 140. The cooling droplets 140 may also be disposed in both the first heat dissipation layer 131 and the second heat dissipation layer 132 to achieve a double-layer heat dissipation effect, which is beneficial to realize efficient heat dissipation for the light plate 110 while sharing the heat dissipation pressure.

Furthermore, a control electrode 161 is disposed in the connection channel 160, and the control electrode 161 is connected to the driver chip 130. The driver chip 130 changes the polarity of the control electrode 161 so that the control electrode 161 forms the valve 128 electrode. When a cooling droplet 140 is disposed under one of two adjacent light-emitting sections 150 and the cooling droplet 140 is in a heat-absorbing state, the driver chip 130 may control the control electrode 161 to close, so that the connection channel 160 between two adjacent light-emitting sections 150 is cut off, and the cooling droplet 140 will not move to the other light-emitting section 150 through the connection channel 160. When the cooling droplet 140 finishes absorbing heat in the light-emitting section 150, the driver chip 130 may control the control electrode 161 to open, so that the connection channel 160 between two adjacent light-emitting sections 150 forms a passage, and the cooling droplet 140 may move from one light-emitting section 150 to another light-emitting section 150 and take away heat from the light-emitting section 150.

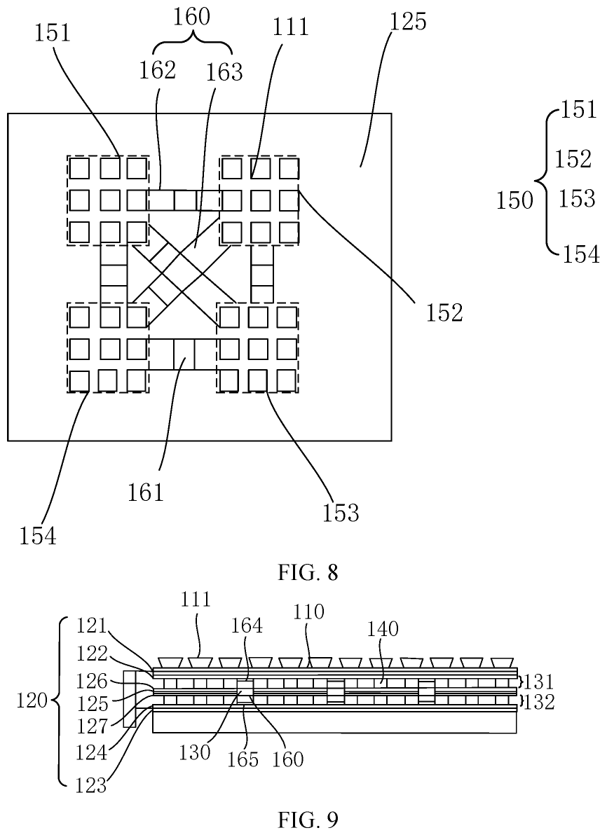

FIG. 8 is a top view of a sixth embodiment of the optical module according to this application. As shown in FIG. 8, the embodiment shown in FIG. 8 is an improvement based on FIG. 6. The light-emitting section 150 includes a first light-emitting section 151, a second light-emitting section 152, a third light-emitting section 153, and a fourth light-emitting section 154 which are adjacently arranged. The first light-emitting section 151, the second light-emitting section 152, the third light-emitting section 153, and the fourth light-emitting section 154 are arranged in a square shape. The connection channel 160 includes a first connection channel 162 and a second connection channel 163. The first connection channel 162 is disposed correspondingly between the first light-emitting section 151 and the second light-emitting section 152, between the second light-emitting section 152 and the third light-emitting section 153, between the third light-emitting section 153 and the fourth light-emitting section 154, and between the fourth light-emitting section 154 and the first light-emitting section 151. The second connection channel 163 is arranged diagonally between the first light-emitting section 151 and the third light-emitting section 153, and between the second light-emitting section 152 and the fourth light-emitting section 154.

Different from the previous embodiment, in this application, a connection channel 160 is disposed between every two of the four adjacent light-emitting sections 150, and each light-emitting section 150 is connected by connection channels 160 from different directions. Through the cooperation of the multiple light-emitting sections 150 with the connection channels 160 between every two light-emitting sections 150, the movement of the cooling droplet 140 no longer relies only on horizontal or vertical movement, or continuous horizontal or continuous vertical movement, to reach the designated heat dissipation area. Instead, the cooling droplet 140 may have more moving paths formed by a combination of different connection channels 160, so that the cooling droplet 140 may move in multiple directions such as horizontal, vertical, and diagonal directions between the four adjacent light-emitting sections 150. This further saves the time for the cooling droplet 140 to reach the designated heat dissipation area, improves the efficiency of movement of the cooling droplet 140, and effectively improves the heat dissipation efficiency of the light plate 110.

FIG. 9 is a schematic diagram of a seventh embodiment of the optical module according to this application. As shown in FIG. 9, the embodiment shown in FIG. 9 is an improvement based on FIG. 6. The first substrate 121 is on one side adjacent to the third substrate 125, and a first electrode 164 is disposed corresponding to the position of the control electrode 161. A first electrode 164 is disposed on the side of the first substrate 121 adjacent to the third substrate 125 and corresponding to the position of the control electrode 161. A second electrode 165 is disposed on the side of the second substrate 123 adjacent to the third substrate 125 and corresponding to the position of the control electrode 161. The first electrode 164 and the second electrode 165 are each electrically connected to the driver chip 130. The driver chip 130 controls the generation of a voltage difference or zero voltage difference between each first electrode 164 and the control electrode 161, and the generation of a voltage difference or zero voltage difference between each second electrode 165 and the control electrode 161. When a voltage difference is formed between each control electrode 161 and the first electrode 164 or the second electrode 165, the coolant drop 140 flows through the connection channel 160. When a zero voltage difference is formed between each control electrode 161 and the first electrode 164 or the second electrode 165, the cooling droplet 140 does not flow through the connection channel 160.

In this embodiment, the first electrode 164 and the second electrode 165 are respectively disposed on the first substrate 121 at a position corresponding to the control electrode 161 of the connection channel 160, and on the second substrate 123 at a position corresponding to the control electrode 161 of the connection channel 160. By means of the electrical changes between the first electrode 164 and the control electrode 161, and between the second electrode 165 and the control electrode 161, the cooling droplet 140 is made to present a hydrophobic state or a hydrophilic state on the connection channel 160 so as to control the cooling droplet 140 to move or remain still between the two light-emitting sections 150 connected by the connection channel 160.

Taking the cooling droplet 140 in the first heat dissipation layer 131 as an example. When the voltage difference between the first electrode 164 and the control electrode 161 is zero, the cooling droplet 140 is hydrophobic between the first electrode 164 and the control electrode 161. At this point, the cooling droplet 140 will flow from one light-emitting section 150 to another light-emitting section 150 through the connection channel 160. When the voltage difference between the first electrode 164 and the control electrode 161 is not zero, the cooling droplet 140 is hydrophilic between the first electrode 164 and the driving electrode. At this point, the cooling droplet 140 will be fixed to the connection channel 160 in a manner similar to “sticking”, and cannot pass from one light-emitting section 150 to another light-emitting section 150 through the connection channel 160. In this way, by changing the electrical properties of the electrodes on the connection channel 160, the cooling droplet 140 may form two states including passable or unpassable through the connection channel 160, so that a “valve”-like effect may be formed between the first electrode 164 and the control electrode 161, and between the second electrode 165 and the control electrode 161, thereby effectively controlling the opening and closing of the connection channel 160 between two adjacent light-emitting sections 150, so that the cooling droplet 140 could be moved to the designated light-emitting section 150 for heat dissipation, and after the heat dissipation is completed, leave the light-emitting section 150 through the connection channel 160, which is beneficial to improve the heat dissipation efficiency of the cooling droplet 140.

Furthermore, the first electrode 164, the second electrode 165, and the control electrode 161 are all made of thermally conductive metal materials. For example, the first electrode 164, the second electrode 165, and the control electrode 161 may be made of Cu, Au, Ag, Al, or other materials. The metals used in the first electrode 164 and the second electrode 165 may need to have good thermal conductivity, so as to further improve the heat dissipation effect on the light-emitting element 111. In addition, the driver chip 130 may relatively quickly control the voltage changes from the first electrode 164 and the second electrode 165 to the driving electrode to control the movement of the cooling droplet 140, thus quickly moving the cooling droplet 140 to the position under the light-emitting element 111 that needs to be cooled, or moving the cooling droplet 140 that has absorbed enough heat to cool the high-temperature light-emitting element 111 to a normal temperature away from the target light-emitting element 111. Through the continuous replenishment and retainment of the cooling droplet 140, a large amount of heat generated by the light-emitting element 111 is taken away, which may control the temperature uniformity of the light plate 110, prevent local overheating of the light plate 110, and quickly cool down the local heat generated by the mini LED in a relatively short period of time.

In addition, the heat dissipation structure 120 in this application may also operate in cooperation with a temperature detection device disposed on the light plate 110. The temperature detection device on the light plate 110 monitors the temperature of each partition or each light-emitting element 111 of the mini LED backlight. One or more threshold temperatures may be set for the temperature detection device. When it is detected that the temperature of one or more partitions or a certain light-emitting element 111 exceeds the threshold temperature, an over-temperature signal may be fed back to the driver chip 130 of the heat dissipation structure 120 so that the coolant replacement frequency is accelerated in the area where the temperature exceeds the threshold temperature, accelerating the heat dissipation of the over-temperature partition or the over-temperature light-emitting element 111, thereby lowering the temperature, making the temperature of the mini LED uniform, and preventing the local temperature from getting too high.

The temperature detection device may be composed of a temperature detection layer in the mini LED light plate 110. The temperature detection layer may be composed of multiple heat-sensitive thin film transistors (the heat-sensitive thin film transistor has a relatively small current at low temperature and a relatively large current at high temperature). The heat-sensitive thin film transistor may monitor the temperature in the optical module 100, in particular, monitor the temperature of each light-emitting element 111/partition. When the temperature of a certain light-emitting element 111/partition exceeds the threshold temperature, a signal is amplified and fed back to the driver chip 130 of the heat dissipation structure 120 to control the replacement frequency of the cooling droplets 140 in this over-temperature area. In addition to this, other partition temperature monitoring methods may also be used, such as a global temperature measuring device, and this application merely uses a temperature detecting device as an example for illustration.

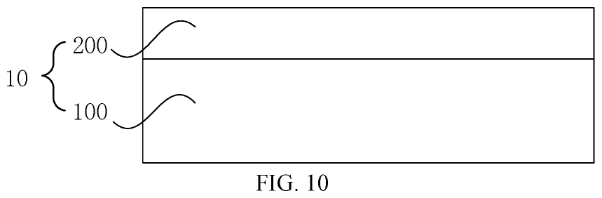

FIG. 10 is a schematic diagram illustrating an embodiment of a display device according to this application. As shown in FIG. 10, this application discloses a display device 10 including a display panel 200. The display device 10 further includes the above-mentioned optical module 100. The display panel 200 is disposed on the side of a light-emitting surface of the optical module 100. The display panel 200 does not emit light by itself, it is the optical module 100 that provides a normal light source for the display panel 200 to ensure normal display of the display panel 200.

The display device 10 of this application may be a television, a computer, a tablet, or other equipment capable of displaying, which is not specifically limited by this application. The optical module 100 in the display device 10 of this application mainly refers to an optical module 100 having a mini LED light plate 110.

Since the mini LED optical module 100 contains a large number of micron-level light-emitting elements 111, for a mini LED containing multiple partitions, when the display panel 200 turns on HDR, the light-emitting elements 111 may have different powers between different partitions, which will lead to huge differences in the heat production between different partitions. In particular, the heat accumulation in a high-brightness display area is relatively more, and the heat accumulation in a low-brightness area is relatively less, which will result in uneven temperature across the entire light plate 110. Long-term use thereof may easily reduce the service life of the local light-emitting element 111, and may also cause abnormalities in the display of the display panel 200.

To address the above problems, this application makes improvements on the optical module 100 in the display device 10. In this application, a heat dissipation structure 120 is arranged under the light plate 110, and in the heat dissipation structure 120, a first anodized aluminum layer 122 and a second anodized aluminum layer 124 are respectively formed on the first substrate 121 and the second substrate 123 both made of aluminum. The surface properties of the first anodized aluminum layer 122 and the second anodized aluminum layer 124 form super-amphiphilic micro-nano channels used for the movement of the cooling droplets 140. By means of the three-phase contact line state of the aluminum plate, the anodized aluminum, and the cooling droplet 140, the cooling droplet 140 may quickly diffuse and move on the porous and orderly anodized aluminum surface, and the cooling droplet 140 may be prevented from splitting while it is moving efficiently, ensuring that the cooling droplet 140 may maintain an effective cooling range and move as a whole. The cooling droplet 140 between the first anodized aluminum layer 122 and the second anodized aluminum layer 124 may quickly wet, cover and absorb the heat of the light-emitting element 111, continuously reducing the temperature of the light-emitting element 111 in the high-temperature display area in a shorter period of time, and ensuring that the temperature difference between adjacent light-emitting elements 111 is relatively small to avoid affecting the display effect, thus further improving the quality of the display device 10.

It should be noted that the inventive concept of this application may be formed into many embodiments, but the length of the application document is limited and so these embodiments cannot be enumerated one by one. The technical features may be arbitrarily combined to form a new embodiment, and the original technical effect may be enhanced after the various embodiments or technical features are combined.

The foregoing is merely a further detailed description of this application with reference to some specific illustrative embodiments, but the specific implementations of this application are not to be limited to these illustrative embodiments. For those having ordinary skill in the technical field to which this application pertains, numerous deductions or substitutions may be made without departing from the concept of this application, and they shall all be regarded as falling in the scope of protection of this application.

What is claimed is:

1. An optical module, comprising a light plate on which a plurality of light-emitting elements are arranged in an array, and further comprising a heat dissipation structure arranged on a side of the light plate facing away from the plurality of light-emitting elements;
wherein the heat dissipation structure comprises a first substrate and a second substrate, the first substrate being arranged above the second substrate and connected to the light plate;
wherein the first substrate and the second substrate are each made of aluminum or an aluminum alloy; wherein there is disposed a first anodized aluminum layer on a side of the first substrate adjacent to the second substrate, and there is disposed a second anodized aluminum layer on a side of the second substrate adjacent to the first substrate; and there is defined a gap between the first anodized aluminum layer and the second anodized aluminum layer, and there is disposed a plurality of cooling droplets in the gap;
wherein in response to each of the plurality of light-emitting elements being at a first heating value, the respective cooling droplet is operative to move to a position under the light-emitting element; and in response to each of the plurality of light-emitting elements being at a second heating value, the respective cooling droplet is operative to leave from under the light-emitting element.

2. The optical module as recited in claim 1, further comprising a third substrate disposed between the first substrate and the second substrate; wherein there is disposed a third anodized aluminum layer on a side of the third substrate adjacent to the first substrate, and a fourth anodized aluminum layer on a side of the third substrate adjacent to the second substrate; wherein the third substrate divides the gap between the first substrate and the second substrate to form a first heat dissipation layer and a second heat dissipation layer, the first heat dissipation layer being located above the second heat dissipation layer;
wherein there are disposed cooling droplets in the first heat dissipation layer, or alternatively there are disposed cooling droplets in each of the first heat dissipation layer and the second heat dissipation layer.

3. The optical module as recited in claim 2, wherein there is disposed at least one valve in the third substrate, and wherein the heat dissipation structure further comprises a driver chip that is arranged outside the third substrate and that is electrically connected to the at least one valve; wherein the driver chip is configured to control opening or closing of the at least one valve to connect or disconnect the first heat dissipation layer and the second heat dissipation layer with or from each other.

4. The optical module as recited in claim 3, wherein there are disposed cooling droplets only in the first heat dissipation layer, and wherein each cooling droplet is disposed correspondingly under the respective light-emitting element, and wherein the third substrate comprises one valve corresponding to a position of each cooling droplet.

5. The optical module as recited in claim 3, wherein a plurality of adjacently arranged light-emitting elements form a light-emitting section; wherein there is disposed a cooling droplet in the first heat dissipation layer at a position corresponding to each of the light-emitting sections, or alternatively there is disposed a cooling droplet in each of the first heat dissipation layer and the second heat dissipation layer at a position corresponding to each of the light-emitting sections, and wherein the cooling droplet has an equal to an area of the light-emitting section;
wherein the third substrate defines a connection channel at a position corresponding to the position between every two adjacent light-emitting sections;
wherein each connection channel comprises a control electrode, which is electrically connected to the driver chip; wherein the driver chip is configured to control a polarity of the control electrode so as to control opening or closing of the respective connection channel.

6. The optical module as recited in claim 5, wherein the light-emitting section comprises a first light-emitting section, a second light-emitting section, a third light-emitting section, and a fourth light-emitting section that are adjacently arranged in a square shape;
wherein the connection channel comprises a first connection channel and a second connection channel; wherein the first connection channel is arranged between the first light-emitting section and the second light-emitting section, between the second light-emitting section and the third light-emitting section, between the third light-emitting section and the fourth light-emitting section, and between the fourth light-emitting section and the first light-emitting section; and
wherein the second connection channel is diagonally connected between the first light-emitting section and the third light-emitting section, and between the second light-emitting section and the fourth light-emitting section.

7. The optical module as recited in claim 5, wherein a first electrode is disposed on a side of the first substrate adjacent to the third substrate and at a position corresponding to the control electrode, and a second electrode is disposed on a side of the second substrate adjacent to the third substrate and at a position corresponding to the control electrode;
wherein the first electrode and the second electrode are each electrically connected to the driver chip, and wherein the driver chip is configured to control each first electrode and the respective control electrode to generate a voltage difference or a zero voltage difference therebetween, and further control each second electrode and the respective control electrode to generate a voltage difference or a zero voltage difference therebetween;
wherein in response to a voltage difference being generated between each control electrode and the respective first electrode or the respective second electrode, the cooling droplet is operative to flow through the respective connection channel; and wherein in response to a zero voltage difference being generated between each control electrode and the respective first electrode or the respective second electrode, the cooling droplet is not operative to flow through the respective connection channel.

8. The optical module as recited in claim 7, wherein the first electrode, the second electrode, and the control electrode are each made of a thermally conductive metal material.

9. The optical module as recited in claim 2, wherein the heat dissipation structure further comprises a low-temperature coolant storage area, a high-temperature coolant storage area, and a cooling device; wherein the low-temperature coolant storage area and the high-temperature coolant storage area are respectively connected to edges of the first substrate and the second substrate in different directions; wherein the low-temperature coolant storage area, the high-temperature coolant storage area, and the cooling device are connected with each other through cooling pipes;
wherein there is disposed a one-way valve in the cooling pipes to control a coolant in the high-temperature coolant storage area to flow to the low-temperature coolant storage area;
wherein the low-temperature coolant storage area and the high-temperature coolant storage area each comprise a plurality of control valves disposed corresponding to the position between the first heat dissipation layer and the second heat dissipation layer; wherein the plurality of control valves are electrically connected to the driver chip, and wherein the driver chip is operative to control opening or closing of each control valve.

10. The optical module as recited in claim 2, wherein the first anodized aluminum layer, the second anodized aluminum layer, the third anodized aluminum layer, and the fourth anodized aluminum layer are each made of micro-nano anodized aluminum.

11. The optical module as recited in claim 1, wherein the first heating value lies in the range of 60° C. to 80° C., and the second heating value lies in the range of 20° C. to 40° C.

12. The optical module as recited in claim 9, wherein the one-way valve is a Tesla one-way valve.

13. The optical module as recited in claim 1, wherein the cooling droplet is a liquid metal or a liquid alloy.

14. The optical module as recited in claim 5, wherein the connection channel is made of a material identical with that of the first anodized layer and the second anodized layer.

15. The optical module as recited in claim 8, wherein the first electrode, the second electrode, and the control electrode are each made of one selected from the group consisting of copper, gold, silver, and aluminum.

16. The optical module as recited in claim 3, wherein the light plate further comprises a temperature detection device configured to monitor a temperature of each of the light-emitting elements.

17. The optical module as recited in claim 16, wherein the temperature detection device is configured to set one or more threshold temperatures; wherein in response to detecting that the temperature of one or more of the light-emitting elements exceeds a threshold temperature, the temperature detection device is configured to feed back an over-temperature signal to the driver chip.

18. The optical module as recited in claim 16, wherein the temperature detection device is comprised of a temperature detection layer in the light plate, and wherein the temperature detection layer is comprised of a plurality of heat-sensitive thin film transistors.

19. A display device, comprising a display panel and further comprising an optical module, wherein the display panel is arranged on a side of a light-emitting surface of the optical module; wherein the optical module comprises a light plate on which a plurality of light-emitting elements are arranged in an array, and further comprises a heat dissipation structure arranged on a side of the light plate facing away from the plurality of light-emitting elements;
wherein the heat dissipation structure comprises a first substrate and a second substrate, the first substrate being arranged above the second substrate and connected to the light plate;
wherein the first substrate and the second substrate are each made of aluminum or an aluminum alloy; wherein there is disposed a first anodized aluminum layer on a side of the first substrate adjacent to the second substrate, and there is disposed a second anodized aluminum layer on a side of the second substrate adjacent to the first substrate; and there is defined a gap between the first anodized aluminum layer and the second anodized aluminum layer, and there is disposed a plurality of cooling droplets in the gap;
wherein in response to each of the plurality of light-emitting elements being at a first heating value, the respective cooling droplet is operative to move to a position under the light-emitting element; and in response to each of the plurality of light-emitting elements being at a second heating value, the respective cooling droplet is operative to leave from under the light-emitting element.
